(19) United States
(12) Patent Application Publication
(10) Pub. No.: US 2012/0068274 A1
(43) Pub. Date: Mar. 22, 2012

(54) SEMICONDUCTOR DEVICE

(75) Inventor: Masanori Kato, Oita-shi (JP)

(73) Assignee: KABUSHIKI KAISHA TOSHIBA, Tokyo (JP)

(21) Appl. No.: 13/053,401

(22) Filed: Mar. 22, 2011

(30) Foreign Application Priority Data
Sep. 17, 2010 (JP) 2010-209224

(51) Int. Cl. H01L 27/092

(52) U.S. Cl. 257/401; 257/E27.062

(57) ABSTRACT

According to one embodiment, a semiconductor device has a substrate comprising an element isolation area, a plurality of tetragonal active areas on the substrate separated by the element isolation area from each other, each of the active areas having an impurity diffusion area, a large active area comprising at least a part of the active areas, an outline of the large active area including a bump. Among the impurity diffusion areas of the active areas, impurity diffusion areas facing through the element isolation area are electrically connected.

### CROSS REFERENCE TO RELATED APPLICATIONS

This application is based upon and claims the benefit of priority from the prior Japanese Patent Application No. 2010-209224 filed on Sep. 17, 2010, the entire contents of which are incorporated herein by reference.

### FIELD

Embodiments described herein relate generally to a semiconductor device.

### BACKGROUND

Conventionally, there has been known a semiconductor device having a complex-shaped active area having a bump in order to decrease a circuit volume while keeping a channel width of a transistor.

However, because there is large unevenness of distribution of a compression stress due to a difference between a coefficient of thermal expansion of a substrate formed of silicon and that of an insulating film in an element isolation area in the complex-shaped active area, there is a problem that unevenness of a current characteristic of the transistor is large.

### BRIEF DESCRIPTION OF THE DRAWINGS

FIG. 1A is a top view of a semiconductor device 100 according to a first embodiment.

FIG. 1B is a top view of the semiconductor device 100 according to the first embodiment.

FIG. 1C is a top view of the semiconductor device 100 according to the first embodiment.

FIG. 2 is a sectional view of a line II-II of FIG. 1C in a vertical direction.

FIG. 3A is a top view of a semiconductor device 200 according to the second embodiment.

FIG. 3B is a top view of the semiconductor device 200 according to a second embodiment.

FIG. 4 is a sectional view of a line IV-IV of FIG. 3B in a vertical direction.

FIG. 5A is a top view of a semiconductor device 300 according to a third embodiment.

FIG. 5B is a top view of the semiconductor device 300 according to the third embodiment.

FIG. 5C is a top view of the semiconductor device 300 according to the third embodiment.

FIG. 6A is a top view of a semiconductor device 400 according to a fourth embodiment.

FIG. 6B is a top view of the semiconductor device 400 according to the fourth embodiment.

FIG. 6C is a top view of the semiconductor device 400 according to the fourth embodiment.

### DETAILED DESCRIPTION

In general, according to one embodiment, a semiconductor device has a substrate comprising an element isolation area, a plurality of tetragonal active areas on the substrate separated by the element isolation area from each other, each of the active areas having an impurity diffusion area, a large active area comprising at least a part of the active areas, an outline of the large active area including a bump. Among the impurity diffusion areas of the active areas, impurity diffusion areas facing through the element isolation area are electrically connected.

Embodiments will now be explained with reference to the accompanying drawings.

(First Embodiment)

(Structure of a Semiconductor Device)

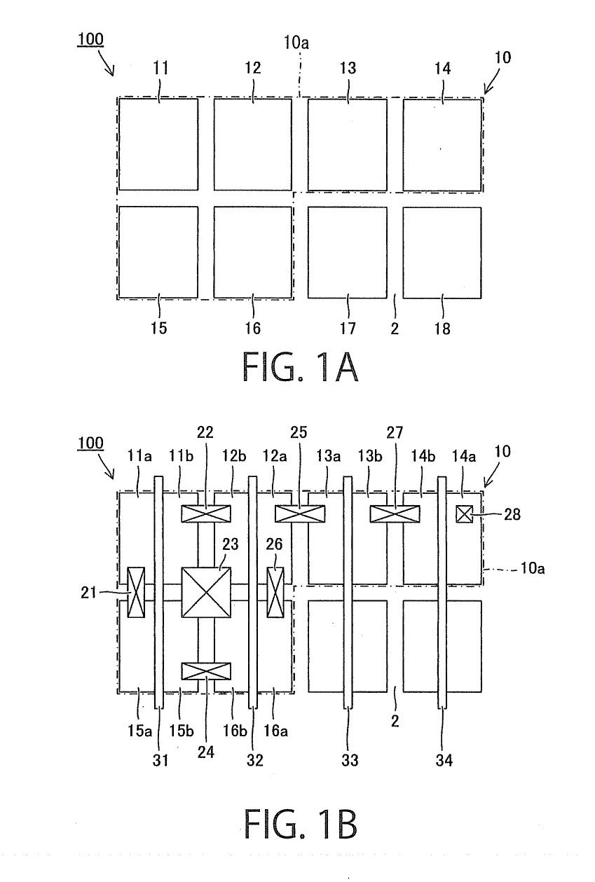

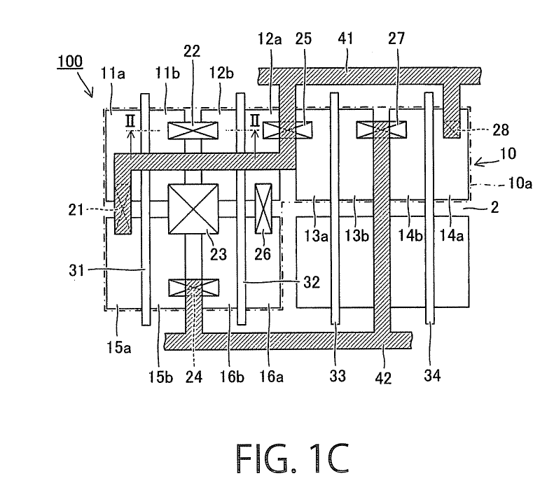

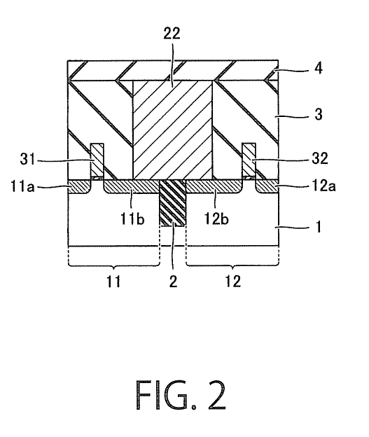

FIGS. 1A, 1B and 1C are top views of a semiconductor device 100 according to a first embodiment. FIG. 2 is a sectional view of a line II-II of FIG. 1C in a vertical direction.

The semiconductor device 100 has a semiconductor substrate 1, an element isolation area 2, active areas 11 to 18, impurity diffusion areas 11a to 16a and 11b to 16b, an interlayer insulating film 3, contact plugs 21 to 28, gate electrodes 31 to 34, a wiring layer insulating film 4, and wires 41 and 42.

The element isolation area 2 is formed on the semiconductor substrate 1. The active areas 11 to 18 are areas on the semiconductor substrate 1 separated by the element isolation area 2 from each other. The impurity diffusion areas 11a to 16a and 11b to 16b are formed in the active areas 11 to 16, respectively. The interlayer insulating film 3 is formed on the semiconductor substrate 1. The contact plugs 21 to 28 and the gate electrodes 31 to 34 are formed in the interlayer insulating film 3. The wiring layer insulating film 4 is formed on the interlayer insulating film 3. The wires 41 and 42 are formed in the wiring layer insulating film 4.

Note that, the interlayer insulating film 3 and the wiring layer insulating film 4 are omitted in FIG. 1C. The interlayer insulating film 3, the wiring layer insulating film 4 and the wires 41 and 42 are omitted in FIG. 1B. The interlayer insulating film 3, the wiring layer insulating film 4, the wires 41 and 42, the contact plugs 21 to 28, the gate electrodes 31 to 34 and the impurity diffusion areas 11a to 16a and 11b to 16b are omitted in FIG. 1A.

The semiconductor substrate 1 is made of a silicon series crystal such as a silicon crystal.

The element isolation area 2 has, for example, an STI (Shallow Trench Isolation) structure, and an insulating material such as SiO₂ is buried therein.

A coefficient of thermal expansion of the material of the semiconductor substrate 1 is different from that of the insulating material in the element isolation area 2.

Due to the difference of the coefficient, a compression stress occurs on the active areas 11 to 18.

A group composed of the active areas 11 to 16 functions as a large active area 10. A shape of an outline 10a of the large active area 10 is complex-shaped having a bump, that is, obtained by combining two or more tetragons having different dimensions. If the active areas 11 to 16 are formed continuously without being isolated by the element isolation area 2, that is, an active area having a shape same as the outline 10a is formed, unevenness of the stress distribution in the active area becomes large due to the complexity of the shape.

The shape of each of the active areas 11 to 16 is tetragon such as square or rectangle, and not complex-shaped having the bump, that is, not a shape obtained by combining two or more tetragons having different dimensions. Therefore, the unevenness of the stress distribution in the active areas 11 to 16 is small, and that in the large active area 10 composed of the active areas 11 to 16 is also small. That is, although the large active area 10 has a complex shape, the unevenness of the stress distribution is small. Furthermore, when the large active area 10 has a more complex shape, the unevenness of the stress distribution can be suppressed by composing the large active area 10 with a group of active areas having tetragonal shape.

Especially, it is preferable that the active areas 11 to 16 have the same shape and the same dimension. Furthermore, it is also preferable that the active areas 11 to 16 are arranged periodically. Because of these, the unevenness of the stress distribution between the active areas 11 to 16 decreases, thereby suppressing the unevenness of the stress distribution of the large active area 10 effectively.

Furthermore, in order to decrease a dimension of the large active area 10, it is preferable that a width of a part of the element isolation area 2 for isolating the active areas 11 to 16 is designed as narrow as possible (for example, 0.05 to 0.1 μm).

The gate electrodes 31 to 34 are, for example, made of polycrystal of silicon series such as polycrystalline silicon having conductive impurities. The gate electrodes 31 to 34 can be metal gate electrodes made of a metal, or can have a double layer structure composed of a metal layer and a polycrystalline layer of silicon series thereon.

The gate electrode 31 is formed above the active area 11 and the active area 15 in common through a gate insulating film. The gate electrode 32 is formed above the active area 12 and the active area 16 in common through the gate insulating film. The gate electrode 33 is formed above the active area 13 and the active area 17 in common through the gate insulating film. The gate electrode 34 is formed above the active area 14 and the active area 18 in common through the gate insulating film.

At both side of the gate electrode 31 in the active area 11, the impurity diffusion areas 11a and 11b are formed. At both side of the gate electrode 32 in the active area 12, the impurity diffusion areas 12a and 12b are formed. At both side of the gate electrode 33 in the active area 13, the impurity diffusion areas 13a and 13b are formed. At both side of the gate electrode 34 in the active area 14, the impurity diffusion areas 14a and 14b are formed. At both side of the gate electrode 31 in the active area 15, the impurity diffusion areas 15a and 15b are formed. At both side of the gate electrode 32 in the active area 16, the impurity diffusion areas 16a and 16b are formed. Note that, the impurity diffusion areas in the active areas 17 and 18 are omitted in FIGS. 1A to 1C.

The impurity diffusion areas 11a to 16a and 11b to 16b are areas having conductive impurities and function as source areas and drain areas of the transistor.

Among the impurity diffusion areas 11a to 16a and 11b to 16b, the impurity diffusion areas 11b and 12b, the impurity diffusion areas 12a and 13a, the impurity diffusion areas 13b and 14b, the impurity diffusion areas 15b and 16b, the impurity diffusion areas 11a to 15a, the impurity diffusion areas 11b and 15b, the impurity diffusion areas 12b and 16b and the impurity diffusion areas 12a and 16a are facing through the element isolation area 2 and electrically connected, respectively.

The bottom of the contact plug 21 contacts to both of the impurity diffusion areas 11a and 15a, and the contact plug 21 electrically connects the impurity diffusion areas 11a and 15a to each other. Similar to this, the contact plug 22 electrically connects the impurity diffusion areas 11b and 12b to each other. The contact plug 24 electrically connects the impurity diffusion areas 15b and 16b to each other. The contact plug 25 electrically connects the impurity diffusion areas 12a and 13a to each other. The contact plug 26 electrically connects the impurity diffusion areas 12a and 16a to each other. The contact plug 27 electrically connects the impurity diffusion area 13b and 14b to each other.

Furthermore, the bottom of the contact plug 23 connects to all of the impurity diffusion areas 11b, 12b, 15b and 16b, and the contact plug 23 connects the impurity diffusion areas 11b, 12b, 15b and 16b to each other. Like this, it is possible to form contact plugs for connecting three or more neighboring impurity diffusion areas. Note that, the contact plugs on the active areas 17 and 18 are omitted in FIGS. 1A to 1C.

The wire 41 is connected to the contact plugs 21 and 28 and at least one of the contact plugs 25 and 26, and not connected to the contact plugs 22, 23, 24 and 27.

The wire 42 is connected to the contact plug 27 and at least one of the contact plugs 22, 23 and 24, and not connected to the contact plugs 21, 25, 26 and 28.

That is, the impurity diffusion areas 11a to 16a are electrically connected to each other through the contact plugs 21, 25, 26 and 28 and the wire 41, and are set to be an identical potential. Furthermore, the impurity diffusion areas lib to 16b are electrically connected to each other through the contact plugs 22, 23, 24 and 27 and the wire 42, and are set to be an identical potential. One of a group composed of the impurity diffusion areas 11a to 16a and a group composed of the impurity diffusion areas lib to 16b functions as the source region of the transistor in the large active area 10, and the other functions as the drain region. By such a structure, the group composed of the active areas 11 to 16 functions as a large active area 10.

The contact plugs 21 to 28 are made of a conductive material such as tungsten (W). The wires 41 and 42 are made of a conductive material such as copper (Cu). The material of the contact plugs 21 to 28 can be the same as that of the wires 41 and 42. The interlayer insulating film 3 and the wiring layer insulating film 4 are made of an insulating material such as SiO₂.

(Second Embodiment)

In a second embodiment, there is a difference from the first embodiment in a structure for connecting the facing impurity diffusion areas in the large active area. Note that, things similar to the first embodiment will be omitted or simplified in the following explanation.

(Structure of Semiconductor Device)

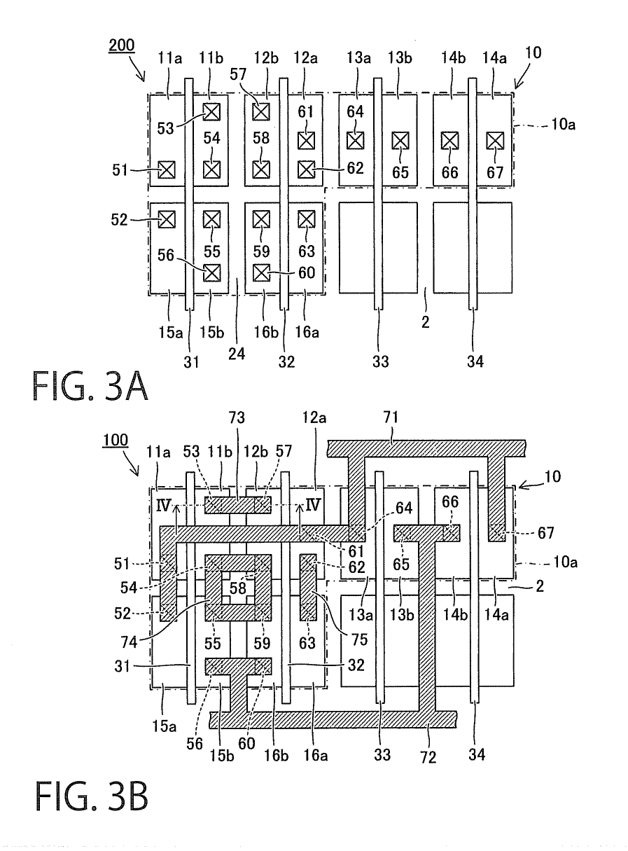

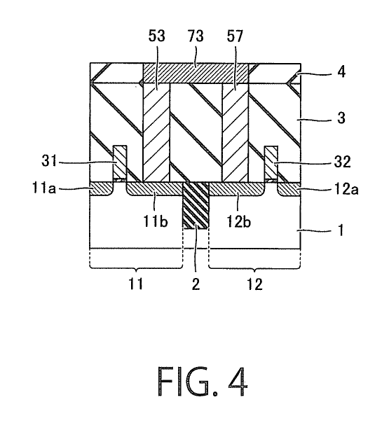

FIGS. 3A and 3B are top views of a semiconductor device 200 according to the second embodiment. FIG. 4 is a sectional view of a line IV-IV of FIG. 3B in a vertical direction.

The semiconductor device 200 has a semiconductor substrate 1, an element isolation area 2, active areas 11 to 18, impurity diffusion areas 11a to 16a and 11b to 16b, an interlayer insulating film 3, contact plugs 51 to 67, gate electrodes 31 to 34, a wiring layer insulating film 4, and wires 71 to 75.

The element isolation area 2 is formed on the semiconductor substrate 1. The active areas 11 to 18 are areas on the semiconductor substrate 1 separated by the element isolation area 2 from each other. The impurity diffusion areas 11a to 16a and 11b to 16b are formed in the active areas 11 to 16, respectively. The interlayer insulating film 3 is formed on the semiconductor substrate 1. The contact plugs 51 to 57 and the gate electrodes 31 to 34 are formed in the interlayer insulating film 3. The wiring layer insulating film 4 is formed on the interlayer insulating film 3. The wires 71 to 75 are formed in the wiring layer insulating film 4.

Note that, the interlayer insulating film 3 and the wiring layer insulating film 4 are omitted in FIG. 3B. The interlayer insulating film 3, the wiring layer insulating film. 4 and the wires 71 to 75 are omitted in FIG. 3A.

Among the impurity diffusion areas 11a to 16a and 11b to 16b, the impurity diffusion areas 11b and 12b, the impurity diffusion areas 12a and 13a, the impurity diffusion areas 13b and 14b, the impurity diffusion areas 15b and 16b, the impurity diffusion areas 11a to 15a, the impurity diffusion areas 11b and 15b, the impurity diffusion areas 12b and 16b and the impurity diffusion areas 12a and 16a are facing through the element isolation area 2 and electrically connected, respectively.

The impurity diffusion areas 11a and 15a are electrically connected to each other by the contact plug 51 on the active area 11a, the contact plug 52 on the impurity diffusion area 15a and the wire 71 connecting the contact plugs 51 and 52 to each other. The impurity diffusion areas 11b and 12b are electrically connected to each other by the contact plug 53 on the impurity diffusion area 11b, the contact plug 57 on the impurity diffusion area 12b and the wire 73 connecting the contact plugs 53 and 57 to each other. The impurity diffusion areas 15b and 16b are electrically connected to each other by the contact plug 56 on the impurity diffusion area 15b, the contact plug 60 on the impurity diffusion area 16b and the wire 72 connecting the contact plugs 56 and 60 to each other. The impurity diffusion areas 12a and 13a are electrically connected to each other by the contact plug 61 on the active area 12a, the contact plug 64 on the impurity diffusion area 13a and the wire 71 connecting the contact plugs 61 and 64 to each other. The impurity diffusion areas 12a and 16a are electrically connected to each other by the contact plug 62 on the active area 12a, the contact plug 63 on the impurity diffusion area 16a and the wire 75 connecting the contact plugs 62 and 63 to each other. The impurity diffusion areas 13b and 14b are electrically connected to each other by the contact plug 65 on the impurity diffusion area 13b, the contact plug 66 on the impurity diffusion area 14b and the wire 72 connecting the contact plugs 65 and 66 to each other.

Furthermore, the impurity diffusion areas 11b, 12b, 15b and 16b are electrically connected to each other by the contact plug 54 on the impurity diffusion area 11b, the contact plug 58 on the impurity diffusion area 12b, the contact plug 55 on the impurity diffusion area 15b, the contact plug 59 on the impurity diffusion area 16b and the wire 74 connecting the contact plugs 54, 58, 55 and 59 to each other. Like this, it is possible to form contact plugs and wires for connecting three or more neighboring impurity diffusion areas. Note that, the contact plugs on the active areas 17 and 18 are omitted in FIGS. 3A and 3B.

The wire 71 is connected to the contact plugs 51, 52, 61, 64 and 67, and not connected to the contact plugs 53, 57, 54, 55, 58, 59, 56, 60, 65 and 66. Note that, that the wire 75 can be connected to the wire 71.

The wire 72 is connected to the contact plug 56, 60, 65 and 66, and not connected to the contact plugs 51, 52, 61, 64, 62, 63 and 67. Note that, that the wires 73 and 74 can be connected to the wire 72.

That is, the impurity diffusion areas 11a and 16a are electrically connected to each other through the contact plugs 51, 52, 61, 64, 62, 63 and 67 and wires 71 and 75, and are set to be an identical potential. Furthermore, the impurity diffusion areas 11b to 16b are electrically connected to each other through the contact plugs 53, 57, 54, 55, 58, 59, 56, 60, 65 and 66 and the wires 72, 73 and 74, and are set to be an identical potential. One of a group composed of the impurity diffusion areas 11a to 16a and a group composed of the impurity diffusion areas lib to 16b functions as the source region of the transistor in the large active area 10, and the other functions as the drain region. By such a structure, the group composed of the active areas 11 to 16 functions as a large active area 10.

The contact plugs 51 to 67 are made of a conductive material such as tungsten (W). The wires 71 to 75 are made of a conductive material such as copper (Cu). The material of the contact plugs 51 to 67 can be the same as that of the wires 71 to 75.

(Third Embodiment)

In a third embodiment, there is a difference from the first embodiment in a structure of the active area in the large active area. Note that, things similar to the first embodiment will be omitted or simplified in the following explanation.

(Structure of Semiconductor Device)

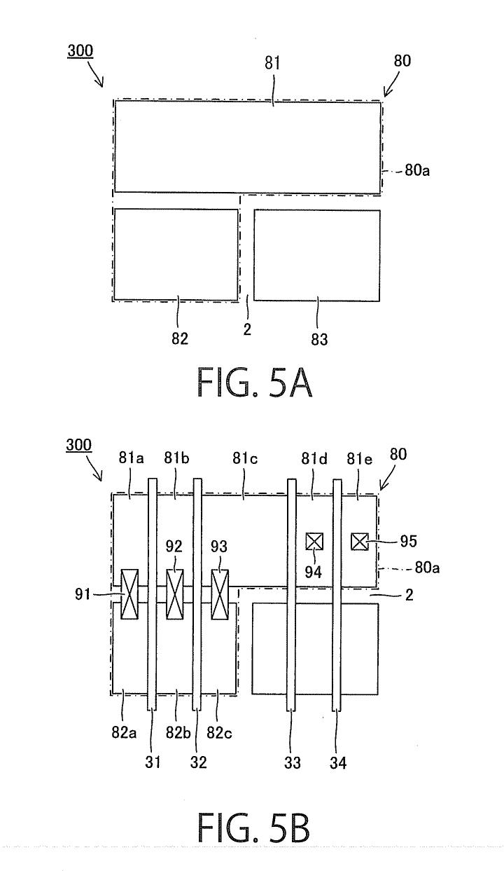

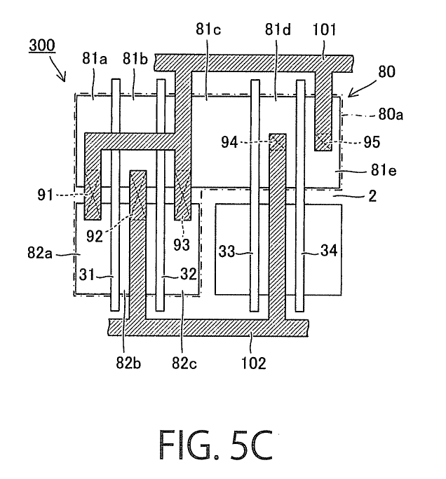

FIGS. 5A and 5C are top views of a semiconductor device 300 according to the third embodiment.

The semiconductor device 300 has a semiconductor substrate 1, an element isolation area 2, active areas 81 to 83, impurity diffusion areas 81a to 81e and 82a to 82c, an interlayer insulating film 3, contact plugs 91 to 95, gate electrodes 31 to 34, a wiring layer insulating film 4, and wires 101 and 102.

The element isolation area 2 is formed on the semiconductor substrate 1. The active areas 81 to 83 are areas on the semiconductor substrate 1 separated by the element isolation area 2 from each other. The impurity diffusion areas 81a to 81e and 82a to 82c are formed in the active areas 81 and 82, respectively. The interlayer insulating film 3 is formed on the semiconductor substrate 1. The contact plugs 91 to 95 and the gate electrodes 31 to 34 are formed in the interlayer insulating film 3. The wiring layer insulating film 4 is formed on the interlayer insulating film 3. The wires 101 and 102 are formed in the wiring layer insulating film 4.

Note that, the interlayer insulating film 3 and the wiring layer insulating film 4 are omitted in FIG. 5C. The interlayer insulating film 3, the wiring layer insulating film 4 and the wires 101 and 102 are omitted in FIG. 5B. The interlayer insulating film 3, the wiring layer insulating film 4, the wires 101 and 102, the contact plugs 91 to 95, gate electrodes 31 to 34 and the impurity diffusion areas 81a to 81e and 82a to 82c are omitted in FIG. 5A.

A group composed of the active areas 81 and 82 functions as a large active area 80. A shape of an outline 80a of the large active area 80 is complex-shaped having a bump, that is, obtained by combining two or more tetragons having different dimensions. If the active areas 81 and 82 are formed continuously without being isolated by the element isolation area 2, that is, an active area having a shape same as the outline 80a is formed, unevenness of the stress distribution in the active area becomes large due to the complexity of the shape.

The shape of each of the active areas 81 and 82 is tetragon such as square or rectangle, and not complex-shaped having the bump, that is, not a shape obtained by combining two or more tetragons having different dimensions. Therefore, the unevenness of the stress distribution in the active areas 81 and 82 is small, and that in the large active area 80 composed of the active areas 81 and 82 is also small. That is, although the large active area 80 has a complex shape, the unevenness of the stress distribution is small.

The active area 81 corresponds to combined active areas to 14 in the first embodiment. The active area 82 corresponds to combined active areas 15 and 16 in the first embodiment. Because the element isolation area 2 is not formed in the active areas 81 and 82, a dimension of the large active area 80 can be smaller than that of the large active area 10 in the first embodiment. That is, by combining a part of active areas under a condition that a shape of each active area is tetragon, it is possible to decrease the dimension of the large active area.

The impurity diffusion areas 81a, 81b, 81c, 81d and 81e are formed at the outside of the gate electrode 31, between the gate electrodes 31 and 32, between the gate electrodes 32 and 33, between the gate electrodes 33 and 34 and at the outside of the gate electrode 34 in the active area 81, respectively. The impurity diffusion areas 82a, 82b and 82c are formed at the outside of the gate electrode 31, between the gate electrodes 31 and 32 and at the outside of the gate electrode 32 in the active area 82, respectively. Note that, the impurity diffusion areas in the active area 83 are omitted in FIGS. 5A to 5C.

The impurity diffusion areas 81a to 81e and 82a to 82c are areas having conductive impurities and function as source areas and drain areas of the transistor.

Among the impurity diffusion areas 81a to 81e and 82a to 82c, the impurity diffusion areas 81a and 82a, the impurity diffusion areas 81b and 82b, and the impurity diffusion areas 81c and 82c are facing through the element isolation area 2 and electrically connected, respectively.

The bottom of the contact plug 91 contacts to both of the impurity diffusion areas 81a and 82a, and the contact plug 91 electrically connects the impurity diffusion areas 81a and 82a to each other. Similar to this, the contact plug 92 electrically connects the impurity diffusion areas 81b and 82b to each other. The contact plug 93 electrically connects the impurity diffusion areas 81c and 82c to each other. Note that, the contact plugs on the active area 83 are omitted in FIGS. 5A to 5C.

The wire 101 is connected to the contact plugs 91, 93 and 95, and not connected to the contact plugs 92 and 94.

The wire 102 is connected to the contact plug 92 and 94, and not connected to the contact plugs 91, 93 and 95.

That is, the impurity diffusion areas 81a, 81c, 81e, 82a and 82c are electrically connected through the contact plugs 91, 93 and 95 and the wire 101, and are set to be an identical potential. Furthermore, the impurity diffusion areas 81b, 81d and 82b are electrically connected through the contact plugs 92 and 94 and the wire 102, and are set to be an identical potential. One of a group composed of the impurity diffusion areas 81a, 81c, 81e, 82a and 82c and a group composed of the impurity diffusion areas 81b, 81d and 82b functions as the source region of the transistor in the large active area 80, and the other functions as the drain region. By such a structure, the group composed of the active areas 81 and 82 functions as a large active area 80.

The contact plugs 91 to 95 are made of a conductive material such as tungsten (W). The wires 101 and 102 are made of a conductive material such as copper (Cu). The material of the contact plugs 91 to 95 can be the same as that of the wires 101 and 102.

(Fourth Embodiment)

In a fourth embodiment, there is a difference from the third embodiment in a point that a dummy gate electrode whose potential is fixed is used for isolating the large active area and a neighboring active area. Note that, things similar to the third embodiment will be omitted or simplified in the following explanation.

(Structure of Semiconductor Device)

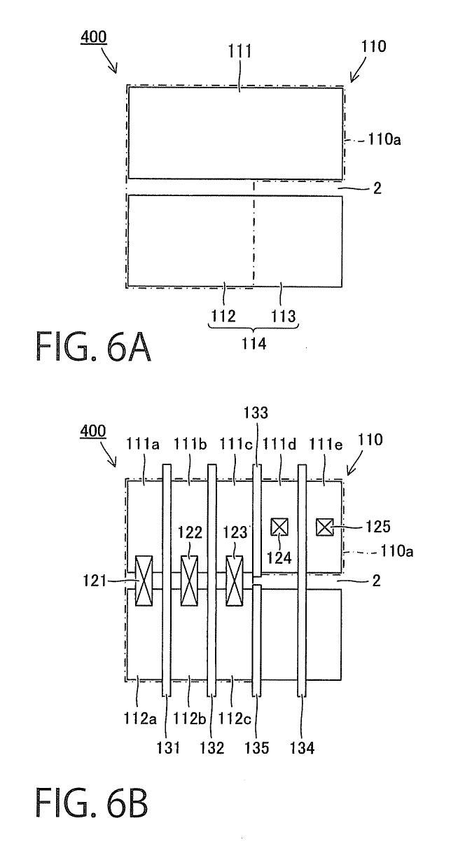

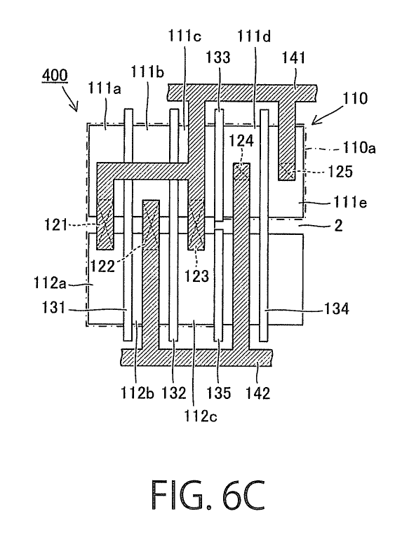

FIGS. 6A to 6C are top views of a semiconductor device 400 according to the fourth embodiment.

The semiconductor device 400 has a semiconductor substrate 1, an element isolation area 2, active areas 111 and 114, impurity diffusion areas 111a to 111e and 112a to 112c, an interlayer insulating film 3, contact plugs 121 to 125, gate electrodes 131 to 134, a dummy gate electrode 135, a wiring layer insulating film 4, and wires 141 and 142.

The element isolation area 2 is formed on the semiconductor substrate 1. The active areas 111 and 114 are areas on the semiconductor substrate 1 separated by the element isolation area 2 from each other. The impurity diffusion areas 111a to 111e and 112a to 112c are formed in the active areas 111 and 114, respectively. The interlayer insulating film 3 is formed on the semiconductor substrate 1. The contact plugs 121 to 125, the gate electrodes 131 to 134, and the dummy gate electrode 135 are formed in the interlayer insulating film 3. The wiring layer insulating film 4 is formed on the interlayer insulating film 3. The wires 141 and 142 are formed in the wiring layer insulating film 4.

Note that, the interlayer insulating film 3 and the wiring layer insulating film 4 are omitted in FIG. 6C. The interlayer insulating film 3, the wiring layer insulating film 4, the wires 141 and 142 are omitted in FIG. 6B. The interlayer insulating film 3, the wiring layer insulating film 4, the wires 141 and 142, the contact plugs 121 to 125, the gate electrodes 131 to 134, the dummy gate electrode 135 and the impurity diffusion areas 111a to 111e and 112a to 112c are omitted in FIG. 6A.

The active area 114 has active areas 112 and 113. Although the active areas 112 and 113 are continuous area and not isolated by the element isolation area 2, the active areas 112 and 113 are electrically insulated by the dummy gate electrode 135. Therefore, the active area 114 functions as isolated two active areas.

The dummy gate electrode 135 is formed above a boundary between the active areas 112 and 113 in the active area 114 through the gate insulating film. The dummy gate electrode 135 is an electrode whose potential is fixed (for example, when the active areas 112 and 113 are negative type, the potential is fixed at 0V), and always functions as a closed gate.

Because the active areas 112 and 113 are isolated by the dummy gate electrode 135, the dimension can be smaller than a case where isolated by the element isolation area 2.

A group composed of the active areas 111 and 112 functions as a large active area 110. A shape of an outline 110a of the large active area 110 is complex-shaped having a bump, that is, obtained by combining two or more tetragons having different dimensions. If the active areas 111 and 112 are formed continuously without being isolated by the element isolation area 2, that is, an active area having a shape same as the outline 110a, unevenness of stress distribution in the active area becomes large due to the complexity of the shape.

The shape of each of the active areas 111 and 114 is tetragon such as square or rectangle, and not complex-shaped, that is, not a shape obtained by combining two or more tetragons having different dimensions. Therefore, the unevenness of the stress distribution in the active areas 111 and 114 is small, and that in the large active area 110 composed of the active areas 111 and 114 is also small. That is, although the large active area 110 has a complex shape, the unevenness of the stress distribution is small.

The impurity diffusion areas 111a, 111b, 111c, 111d and 111e are formed at the outside of the gate electrode 131, between the gate electrodes 131 and 132, between the gate electrodes 132 and 133, between the gate electrodes 133 and 134 and at the outside of the gate electrode 134 in the active area 111, respectively. The impurity diffusion areas 112a, 112b and 112c are formed at the outside of the gate electrode 131, between the gate electrodes 131 and 132 and at the outside of the gate electrode 132 in the active area 112, respectively. Note that, the impurity diffusion areas in the active area 113 are omitted in FIGS. 6A to 6C.

The impurity diffusion areas 111a to 111e and 112a to 112c are areas having conductive impurities and function as source areas and drain areas of the transistor.

Among the impurity diffusion areas 111a to 111e and 112a to 112c, the impurity diffusion areas 111a and 112a, the impurity diffusion areas 111b and 112b, and the impurity diffusion areas 111c and 112c are facing through the element isolation area 2 and electrically connected, respectively.

The bottom of the contact plug 121 contacts to both of the impurity diffusion areas 111a and 112a, and the contact plug 121 electrically connects the impurity diffusion areas 111a and 112a to each other. Similar to this, the contact plug 122 electrically connects the impurity diffusion areas 111b and 112b to each other. The contact plug 123 electrically connects the impurity diffusion areas 111c and 112c to each other. Note that, the contact plugs on the active area 113 are omitted in FIGS. 6A to 6C.

The wire 141 is connected to the contact plugs 121, 123 and 125, and not connected to the contact plugs 122 and 124.

The wire 142 is connected to the contact plug 122 and 124, and not connected to the contact plugs 121, 123 and 125.

That is, the impurity diffusion areas 111a, 111c, 111e, 112a and 112c are electrically connected through the contact plugs 121, 123 and 125 and the wire 141, and are set to be an identical potential. Furthermore, the impurity diffusion areas 111b, 111d and 112b are electrically connected through the contact plugs 122 and 124 and the wire 142, and are set to be an identical potential. One of a group composed of the impurity diffusion areas 111a, 111c, 111e, 112a and 112c and a group composed of the impurity diffusion areas 111b, 111d and 112b functions as the source region of the transistor in the large active area 110, and the other functions as the drain region. By such a structure, the group composed of the active areas 111 and 112 functions as a large active area 110.

The contact plugs 121 to 125 are made of a conductive material such as tungsten (W). The wires 141 and 142 are made of a conductive material such as copper (Cu). The material of the contact plugs 121 to 125 can be the same as that of the wires 141 and 142.

(Effect of the Embodiments)

According to the first to the fourth embodiment, even if a large active area having a complex shape is formed in order to decrease a circuit volume while keeping a channel width of a transistor, the unevenness of the stress distribution in the large active area can be suppressed by forming the large active area by a group of tetragonal active areas.

Furthermore, because each of the active areas composing the large active area has a simple shape of tetragon, the active areas can be formed with high accuracy.

(Other Embodiments)

The present invention is not limited to the above embodiments, and can be variously modified within the purpose of the invention. For example, the shape, size, number and arrangement and so on of the active area, the contact plug and wires are not limited to the above.

Furthermore, within the purpose of the invention, components of the above embodiments can be combined arbitrarily. For example, the third or fourth embodiments can be combined with the second embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A semiconductor device comprising:
a substrate comprising an element isolation area;
a plurality of tetragonal active areas on the substrate separated by the element isolation area from each other, each of the active areas having an impurity diffusion area; and
a large active area comprising at least a part of the active areas, an outline of the large active area including a bump,
wherein among the impurity diffusion areas of the active areas, impurity diffusion areas facing through the element isolation area are electrically connected.

2. The device of claim 1, wherein at least one facing pair of the impurity diffusion areas facing through the element isolation area are connected by at least a first contact plug whose bottom contacts both of the pair of impurity diffusion areas.

3. The device of claim 1, wherein the element isolation area comprises:
a first element isolation area formed in a first direction; and
a second element isolation area formed in a second direction intersecting with the first direction,
at least one of the active areas comprises:
a first active area and a second active area separated by the first element isolation area from each other;
a third active area separated from the first active area by the second element isolation area; and
a fourth active area separated from the second active area by the first element isolation area and separated from the third active area by the first element isolation area,
wherein the impurity diffusion areas of the first to the fourth active areas are connected by a first contact plug whose bottom contacts all of the impurity diffusion areas of the first to the fourth active areas.

4. The device of claim 1, wherein at least one facing pair of the impurity diffusion areas facing through the element isolation area are connected by second contact plugs and a wire, each of the second contact plugs being connected to each of the pair of the impurity diffusion areas, and the wire connecting the second contact plugs to each other.

5. The device of claim 1, wherein the element isolation area comprises:
a first element isolation area formed in a first direction; and
a second element isolation area formed in a second direction intersecting with the first direction,
at least one of the active areas comprises:
a first active area and a second active area separated by the element isolation area from each other;
a third active area separated from the first active area by the second element isolation area; and
a fourth active area separated from the second active area by the first element isolation area and separated from the third active area by the first element isolation area,
wherein the impurity diffusion areas of the first to the fourth active areas are connected by second contact plugs and a wire, each of the second contact plugs being connected to each of the impurity diffusion areas, and the wire connecting the second contact plugs to each other.

6. The device of claim 1 further comprising a plurality of gate electrodes above the active areas,
wherein each of the impurity diffusion areas comprises:
a first impurity diffusion area at one side of each of the gate electrodes; and
a second impurity diffusion area at the other side of each of the gate electrodes.

7. The device of claim 6, wherein at least one of the gate electrodes is formed in common above at least a pair of the active areas of the active areas separated by the element isolation area.

8. The device of claim 7, wherein one of the gate electrodes is orthogonal to the element isolation area separating at least the pair of the active areas.

9. The device of claim 6, wherein at least two of the first and the second impurity diffusion areas are set to be a first potential, and the others are set to be a second potential.

10. The device of claim 1, wherein the active areas have an identical shape and an identical dimension.

11. The device of claim 1, wherein the active areas are arranged periodically.

12. The device of claim 1, wherein at least one of the active areas comprises:
a first active area out of the large active area and neighboring the large active area; and
a second active area continuous to the first active area,
wherein the first active area is electrically separated from the second active area by a dummy gate electrode whose potential is fixed at a predetermined potential.

13. The device of claim 12, wherein the predetermined potential is set according to a polarity of the first and the second active areas.

14. The device of claim 1, wherein a shape of the large active area is obtained by combining two or more tetragons each of which has a different dimension.
